(19) United States
(12) Patent Application Publication
(10) Pub. No.: US 2014/0001037 A1
(43) Pub. Date: Jan. 2, 2014

(54) WINDPIPE FOR VACUUM COATING DEVICE AND VACUUM COATING DEVICE USING THE WINDPIPE

(71) Applicants: SHENZHEN FUTAIHONG PRECISION INDUSTRY CO., LTD., Shenzhen (CN); FIH (HONG KONG) LIMITED, Kowloon (HK)

(72) Inventor: DA-HUA CAO, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/693,221

(22) Filed: Dec. 4, 2012

(30) Foreign Application Priority Data
Jun. 29, 2012 (CN) 2012102209953

(51) Int. Cl. C23C 14/22; F16L 9/18

(52) U.S. Cl. CPC C23C 14/228; F16L 9/18
USPC 204/298.07; 138/114

(57) ABSTRACT

A windpipe used in a vacuum coating device includes an outer pipe and an inner pipe positioned in the outer pipe. The inner pipe defines a plurality of first outlets arranged in a line in the peripheral wall of the inner pipe along the axial direction. The outer pipe defines a plurality of second outlets arranged in a line in the peripheral wall of the outer pipe along the axial direction.

### BACKGROUND

1. Technical Field

The present disclosure relates to a windpipe and a vacuum coating device using the windpipe.

2. Description of Related Art

Physical vapor deposition (PVD) processes are environmentally friendly and are widely used for coating substrates. The PVD process is implemented in a vacuum coating device including a vacuum chamber. Commonly, windpipes are configured for transporting work gases and reaction gases in the vacuum chamber. The current windpipe is usually a single pipe defining a plurality of outlets in the peripheral wall of the windpipe along the axial direction. However, gases guided by the current windpipe can hardly distribute uniformly in the vacuum chamber, which results PVD films inconsistent colors.

Therefore, there is room for improvement within the art.

### BRIEF DESCRIPTION OF THE FIGURE

Many aspects of the windpipe and the vacuum coating device can be better understood with reference to the following drawings. The components in the drawings are not necessarily drawn to scale, the emphasis instead being placed upon clearly illustrating the principles of the windpipe and the vacuum coating device. Moreover, in the drawings like reference numerals designate corresponding parts throughout the several views. Wherever possible, the same reference numbers are used throughout the drawings to refer to the same or like elements of an embodiment.

FIG. 1 is a schematic view of an exemplary windpipe.

FIG. 2 is a cross-sectional view of an exemplary vacuum coating device.

### DETAILED DESCRIPTION

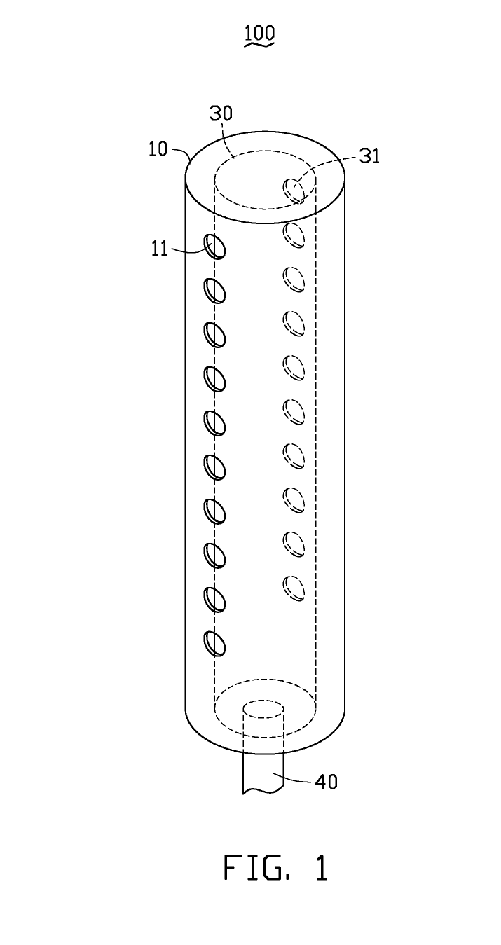

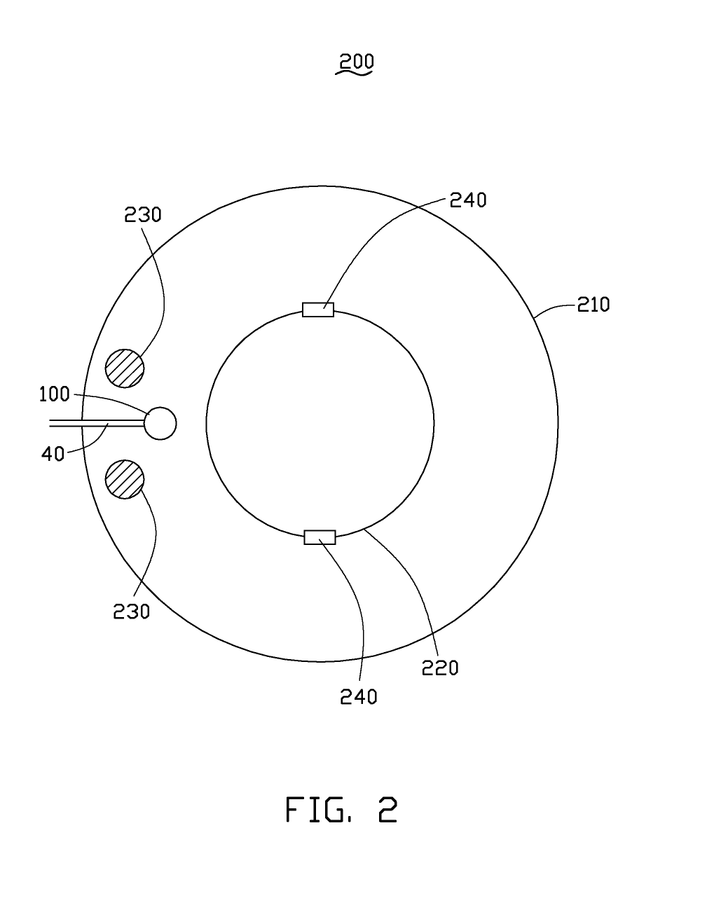

FIGS. 1 and 2 show a windpipe 100 used in a vacuum coating device 200 according to an exemplary embodiment. The windpipe 100 includes an outer pipe 10 and an inner pipe 30 positioned in the outer pipe 10. The outer pipe 10 inner diameter is no less than two times of the inner pipe 30 inner diameter.

The inner pipe 30 has a peripheral wall and defines a plurality of first outlets 31 arranged in a line in the inner pipe 30 peripheral wall along an axial direction. The outer pipe 10 has a peripheral wall and defines a plurality of second outlets 11 arranged in a line in the outer pipe 10 peripheral wall of the outer pipe 10 along an axial direction. The line of all the first outlets 31 and the line of all the second outlets 11 are parallel. In one embodiment, the first outlets 31 and the second outlets 11 are diametrically opposed, the distance between the line of all the first outlets 31 to the line of all the second outlets 11 is maximized.

The first outlets 31 and the second outlets 11 may have shapes such as round, square, and oval, for example. When the first outlets 31 and the second outlets 11 are round, the diameters of each first outlets 31 and each second outlets 11 is about 0.3 mm to about 2.0 mm, and in one embodiment, each first outlet 31 and each second outlet 11 are about 0.5 mm. The second outlets 11 are equidistantly arranged in the outer pipe 10, that is, the distances between each two adjacent second outlets 11 are the same. The first outlets 31 may be equidistantly arranged in the inner pipe 30 or not, that is, the distances between each two adjacent first outlets 31 are the same or not.

FIG. 2 shows that the inner pipe 30 has a first end and a second end, and the first end of the inner pipe 30 connects an intake pipe 40, the second end of the inner pipe 30 is sealed. The outer piper has two sealed ends. Gas guided by the intake pipe 40 first enter the inner pipe 30 and then is exhausted from the first outlets 31, during which the gas diffuses to the outer pipe 10 and subsequently is exhausted from the second outlets 11 to the vacuum chamber. As such, the gas can uniformly distribute along the extension direction of the windpipe 100.

The vacuum coating device 200 includes a vacuum chamber 210, targets 230, a rotable rack 220 for loading substrates 240, and the windpipe 100 positioned in the vacuum chamber 210. The second outlets 11 faces the rotable rack 220, for which the reaction gas can mainly react with the target atoms sputtered from the targets 230 at the substrate 240.

The exemplary windpipe 100 includes the outer piper 10 and the inner pipe 30 both defining outlets. As such, the gas can uniformly be distributed along the extension direction of the windpipe 100 as well as the vacuum chamber 210. As a result, each PVD film has consistent thickness and color.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A windpipe used in vacuum coating device, the windpipe comprising:
an outer pipe, the outer pipe having a peripheral wall and defining a plurality of second outlets arranged in a line in the outer pipe peripheral wall along an axial direction; and
an inner pipe positioned in the outer pipe, the inner pipe having a peripheral wall and defining a plurality of first outlets arranged in a line in the inner pipe peripheral wall along an axial direction.

2. The windpipe as claimed in claim 1, wherein the line of all the first outlets and the line of all the second outlets are parallel, and the distance between the line of all the first outlets to the line of all the second outlets is maximized.

3. The windpipe as claimed in claim 1, wherein an outer pipe inner diameter is no less than two times of an inner pipe inner diameter.

4. The windpipe as claimed in claim 1, wherein the plurality first outlets and the plurality second outlets are round, square or oval.

5. The windpipe as claimed in claim 1, wherein the plurality first outlets and the plurality second outlets are round, the diameters of each first outlet and each second outlet are about 0.3 mm to about 2.0 mm.

6. The windpipe as claimed in claim 5, wherein the diameters of each first outlet and each second outlet are about 0.5 mm.

7. The windpipe as claimed in claim 1, wherein the inner pipe has a first end and a second end, the first end of the inner pipe connects an intake pipe, the second end of the inner pipe is sealed; the outer pipe has two sealed ends.

8. The windpipe as claimed in claim 1, wherein distances between each two adjacent second outlets are equal.

9. A vacuum coating device, comprising:
a vacuum chamber;
a rack configured in the vacuum chamber for loading substrate; and
a windpipe positioned in the vacuum chamber, the windpipe comprising:
an outer pipe, the outer pipe having a peripheral wall and defining a plurality of second outlets arranged in a line in the outer pipe peripheral wall along an axial direction; and an inner pipe positioned in the outer pipe, the inner pipe having a peripheral wall and defining a plurality of first outlets arranged in a line in the inner pipe peripheral wall along an axial direction, the second outlets facing the rack.

10. The vacuum coating device as claimed in claim 9, wherein the line of all the first outlets and the line of all the second outlets are parallel, and the distance between the line of all the first outlets to the line of all the second outlets is maximized.

11. The vacuum coating device as claimed in claim 9, wherein the inner diameter of the outer pipe is no less than two times of the inner diameter of the inner pipe.

12. The vacuum coating device as claimed in claim 9, wherein the plurality first outlets and the plurality second outlets are round, square or oval.

13. The vacuum coating device as claimed in claim 9, wherein the plurality first outlets and the second outlets are round, the diameters of each first outlets and each second outlets are about 0.3 mm to about 2.0 mm.

14. The vacuum coating device as claimed in claim 13, wherein the diameters of each first outlets and each second outlets are about 0.5 mm.

15. The vacuum coating device as claimed in claim 9, wherein the inner pipe has a first end and a second end, the first end of the inner pipe connects an intake pipe, the second end of the inner pipe is sealed; the outer pipe has two sealed ends.

16. The vacuum coating device as claimed in claim 9, wherein distances of each two adjacent second outlets are equal.
